(19) United States
(12) Patent Application Publication
(10) Pub. No.: US 2024/0363640 A1
(43) Pub. Date: Oct. 31, 2024

(54) DISPLAY PANEL AND DISPLAY DEVICE

(71) Applicant: Wuhan China Star Optoelectronics Technology Co., Ltd., Wuhan (CN)

(72) Inventors: Fei AI, Wuhan (CN); Dewei SONG, Wuhan (CN); Chengzhi LUO, Wuhan (CN)

(21) Appl. No.: 18/522,308

(22) Filed: Nov. 29, 2023

Related U.S. Application Data
(63) Continuation of application No. PCT/CN2023/103112, filed on Jun. 28, 2023.

(30) Foreign Application Priority Data
Apr. 28, 2023 (CN) 202310501130.2

(51) Int. Cl. H01L 27/12

(52) U.S. Cl. CPC H01L 27/1222; H01L 27/124

(57) ABSTRACT

A display panel and a display device are provided. The display panel includes: an active layer, a gate, and a gate auxiliary structure. The active layer is disposed along a first direction and includes a channel layer. The gate is disposed above the channel layer and a width of the gate along the first direction is equal to a length of the channel layer along the first direction. The gate auxiliary structure is disposed adjacent to the gate. The width of the gate along the first direction is less than 1 micrometer.

### CROSS-REFERENCE TO RELATED APPLICATIONS

This application is a continuation application of International Application No. PCT/CN2023/103112, filed on Jun. 28, 2023, which claims priority to Chinese Application No. 202310501130.2, filed on Apr. 28, 2023, both of which are incorporated herein by reference in their entireties.

### FIELD

The present disclosure relates to display technologies, and more particularly, to a display panel and a display device.

### BACKGROUND

With development of display technologies, flat panel display devices, such as a liquid crystal display (LCD) and an organic light-emitting diode (OLED) display, have been widely used in various consumer electronics, such as mobile phones, televisions, personal digital assistants, digital cameras, laptops, desktop computers, etc. because of their advantages, such as high definition, power saving, thin body, wide application range, etc. Therefore, the flat panel display devices have become a mainstream of display devices.

With continuous development of panel industries, higher requirements have been put forward for the display panels, such as a narrow border, a high aperture ratio, high brightness, high resolution, etc. Manufacturing of the panels also faces new challenges, especially in emerging fields of the display technology, such as virtual reality (VR)/augmented reality (AR) displays, panel system integration, etc. It is necessary for an array substrate to be designed in a device size with ultra-high pixels per inch (PPI) and submicron level. In order to meet these requirements, it is necessary to minimize the device size and the occupied area of the array substrate as much as possible.

Therefore, how to reduce a length of a channel layer in the array substrate is an important research direction.

### SUMMARY

A display panel according to the present disclosure includes:
an active layer, disposed along a first direction and including a channel layer;
a gate above the channel layer, a width of the gate along the first direction being equal to a length of the channel layer along the first direction; and
a gate auxiliary structure adjacent to the gate;
the width of the gate along the first direction being less than 1 micrometer.

In one or more embodiments, the active layer further includes:
a first ohmic contact layer and a second ohmic contact layer, the first ohmic contact layer and the second ohmic contact layer being disposed on two ends of the channel layer, respectively, and the channel layer being disposed between the first ohmic contact layer and the second ohmic contact layer; and
a first transition layer between the first ohmic contact layer and the channel layer.

In one or more embodiments, the gate auxiliary structure is disposed on a side wall of the gate along the first direction, and an orthographic projection of the first transition layer on the gate auxiliary structure is disposed in the gate auxiliary structure.

In one or more embodiments, the gate auxiliary structure is disposed on a side wall of the gate along the first direction, and an orthographic projection of the first ohmic contact layer on the gate auxiliary structure is disposed in the gate auxiliary structure.

In one or more embodiments, the display panel further includes a source and a drain; the source and the drain are connected to the first ohmic contact layer and the second ohmic contact layer, respectively, and the source penetrates the gate auxiliary structure.

In one or more embodiments the active layer further includes a second transition layer between the second ohmic contact layer and the channel layer.

In one or more embodiments, the gate auxiliary structure is disposed on the gate, and a width of the gate auxiliary structure along the first direction is equal to the width of the gate along the first direction.

In one or more embodiments, the gate auxiliary structure is further disposed above a second ohmic contact layer and two side walls of a gate wiring along the first direction.

In one or more embodiments, the first ohmic contact layer and the second ohmic contact layer are doped with N-type semiconductor materials, the first transition layer is doped with a P-type semiconductor material; and a doping concentration of each of the first ohmic contact layer and the second ohmic contact layer is greater than a doping concentration of the first transition layer.

In one or more embodiments, the second ohmic contact layer includes a first concentration region close to the channel layer and a second concentration region away from the channel layer, and a doping concentration of the first concentration region is lower than a doping concentration of the second concentration region.

A display device according to the present disclosure includes the display panel according to any one of the above embodiments.

### BRIEF DESCRIPTION OF THE DRAWINGS

With reference to the accompanying drawings, specific implementation modes of the present disclosure are described in details, thereby making technical solutions of the present disclosure and technical effects thereof apparent.

FIG. 1 illustrates a schematic structural diagram of a cross-sectional view of a display panel according to one or more embodiments of the present disclosure.

FIG. 2 illustrates a schematic structural diagram of a top view of the display panel in FIG. 1 according to one or more embodiments of the present disclosure.

FIG. 3 illustrates a schematic structural diagram of a cross-sectional view of a display panel according to one or more embodiments of the present disclosure.

FIG. 4 illustrates a schematic structural diagram of a top view of the display panel in FIG. 3 according to one or more embodiments of the present disclosure.

FIG. 5 illustrates a schematic structural diagram of a cross-sectional view of a display panel according to one or more embodiments of the present disclosure.

FIG. 6 illustrates a schematic flowchart of a manufacturing method of a display panel according to one or more embodiments of the present disclosure.

FIGS. 7A to 7E illustrate schematic structural diagrams of a display panel during a manufacturing method according to one or more embodiments of the present disclosure.

FIGS. 8A to 8G illustrate schematic structural diagrams of a display panel during a manufacturing method according to one or more embodiments of the present disclosure.

### DETAILED DESCRIPTION

The following will provide a clear and complete description of the technical solutions in one or more embodiments of the present disclosure with reference to the accompanying drawings. Apparently, the described one or more embodiments are only some of the embodiments of the present disclosure, not all of the embodiments. Based on one or more embodiments in the present disclosure, all of other embodiments obtained by those skilled in the related art without creative labor fall within the scope of the protection of the present disclosure.

In the description of the present disclosure, it should be understood that terms, such as “first” and “second”, are only used for descriptive purposes and cannot be understood as indicating or implying relative importance, or implying a quantity of described technical features. Therefore, features limited by the terms of “first” and “second” may explicitly or implicitly include one or more of the described features. In the description of the present disclosure, “multiple” means two or more, unless otherwise specified.

In the present disclosure, unless otherwise explicitly specified and limited, the first feature “disposed above” or “disposed below” the second feature may include a direct contact between the first feature and the second feature, or it may include a contact between the first feature and the second feature not directly but through additional features between them. Moreover, the first feature “disposed on”, “disposed over”, and “disposed above” the second feature includes the first feature directly above and diagonally above the second feature, or simply indicates that a horizontal height of the first feature is higher than that of the second feature. The first feature “disposed under”, “disposed downward”, and “disposed below” the second feature includes the first feature directly below and diagonally below the second feature, or simply indicates that a horizontal height of the first feature is less than that of the second feature.

The present disclosure provides many different implementation modes or embodiments to implement different structures of the present disclosure as follows. In order to simplify the present disclosure, components and settings of illustrated embodiments will be described below. Certainly, the illustrated embodiments are only illustrative and are not intended to limit the present disclosure. In addition, the present disclosure may repeat reference numbers and/or reference letters in different embodiments, which aims to simplify and clarity the present disclosure, and does not indicate a relationship between the various embodiments and/or settings discussed. Moreover, the present disclosure provides the illustrated embodiments with various specific processes and materials, but those skilled in the related art may be aware that other processes and/or other materials may be applied in the present disclosure.

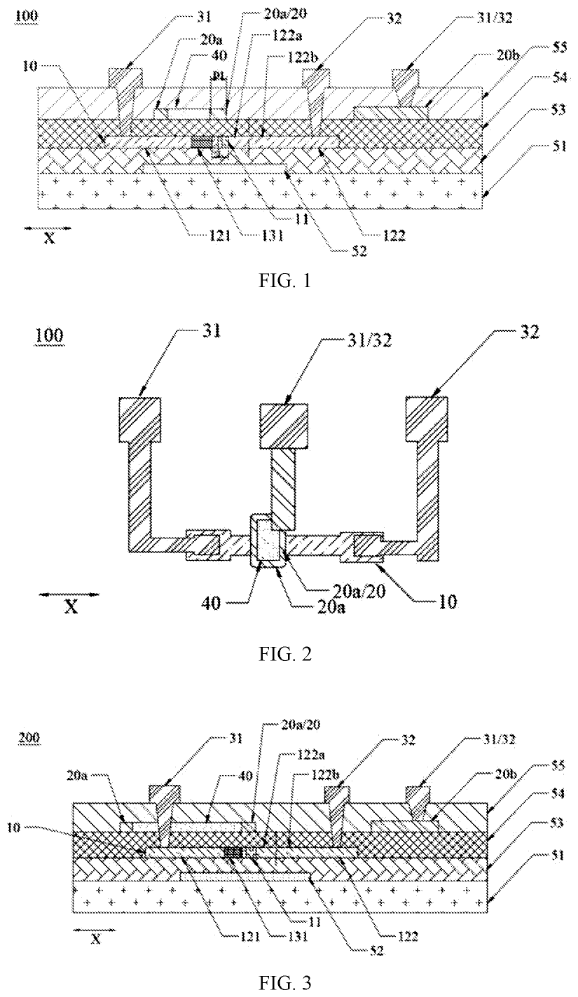

With reference to FIG. 1, FIG. 1 illustrates a schematic structural diagram of a cross-sectional view of a display panel according to one or more embodiments of the present disclosure. A display panel 100 may include a thin-film transistor, such as a low-temperature polycrystalline silicon transistor, a metal oxide transistor, etc. The display panel 100 may be used in various electronic devices, such as a wearable device (e.g., a smart wristband, a smart watch, a virtual reality abbreviated as VR device, etc.), a mobile phone, an e-book, electronic newspaper, a television, a personal laptop, and flexible display and lighting devices that are foldable and rollable.

The display panel 100 may include an active layer 10, a gate 20, and a gate auxiliary structure 40. The active layer 10 is disposed along a first direction (X) and includes a channel layer 11. The gate 20 is opposite to and above the channel layer 11, and a width D1 of the gate 20 along the first direction (X) is equal to a length L of the channel layer 11 along the first direction (X). Therefore, the length L of the channel layer 11 is determined by the width D1 of the gate 20. The width D1 of the gate 20 along the first direction (X) is less than 1 micrometer, and then the length L of the channel layer 11 along the first direction (X) is also less than 1 micrometer.

The gate auxiliary structure 40 is disposed above the active layer 10 and is disposed adjacent to the gate 20. The gate auxiliary structure 40 is configured to assist in a formation of the gate 20, and the gate auxiliary structure 40 may be made of silicon nitride and/or silicon oxide.

In one or more embodiments, the width D1 of the gate 20 along the first direction (X) is in a range of 0.05˜0.5 micrometer.

In one or more embodiments, the active layer 10 may also include a first ohmic contact layer 121 and a second ohmic contact layer 122, as well as a first transition layer 131. The first ohmic contact layer 121 and the second ohmic contact layer 122 are respectively disposed at two ends of the active layer 10, the channel layer 11 is disposed between the first ohmic contact layer 121 and the second ohmic contact layer 122, and the first transition layer 131 is disposed between the first ohmic contact layer 121 and the channel layer 11.

In one or more embodiments, the active layer 10 may also include a second transition layer (not shown in FIG. 1), which is disposed between the second ohmic contact layer 122 and the channel layer 11.

Specially, the active layer 10 may be made of low-temperature polycrystalline silicon or a semiconductor oxide, the first ohmic contact layer 121 and the second ohmic contact layer 122 may be the active layer 10 doped with a N-type semiconductor material, the first transition layer 131 and the second transition layer may be the active layer 10 doped with a P-type semiconductor material, and the channel layer 11 may be the active layer 10 doped with no material. And the first ohmic contact layer 121 and the second ohmic contact layer 122 are heavily doped, while the first transition layer 131 and the second transition layer are slightly doped, that is, a doping concentration of each of the first ohmic contact layer 121 and the second ohmic contact layer 122 is greater than a doping concentration of each of the first transition layer 131 and the second transition layer.

In one or more embodiments, the second ohmic contact layer 122 further includes a first concentration region 122a close to the channel layer 11 and a second concentration region 122b away from the channel layer 11. A doping concentration of the first concentration region 122a is less than a doping concentration of the second concentration region 122b. The doping concentration of the second concentration region 122b may be equal to the doping concentration of the first ohmic contact layer 121.

The display panel 100 may also include a source 31 and a drain 32. The source 31 and the drain 32 are connected to the first ohmic contact layer 121 and the second ohmic contact layer 122, respectively. The first ohmic contact layer 121 and the second ohmic contact layer 122 are used to reduce a contact resistance between the source 31 and the active layer 10, and a contact resistance between the drain 32 and the active layer 10, respectively. The active layer 10, the gate 20, the source 31, and the drain 32 may together form a thin-film transistor. The first transition layer 131 is disposed between the first ohmic contact layer 121 and the channel layer 11, which can prevent a current in the channel layer 11 from leaking into the first ohmic contact layer 121 when the thin-film transistor is turned off. The second transition layer is disposed between the second ohmic contact layer 122 and the channel layer 11, which can prevent a current in the channel layer 11 from leaking into the second ohmic contact layer 122 when the thin-film transistor is turned off.

In one or more embodiments, the display panel 100 may also include a substrate 51, a light shielding layer 52, a buffer layer 53, a gate insulating layer 54, and a dielectric layer 55. The light shielding layer 52 is disposed on the substrate 51, the buffer layer 53 is disposed on the substrate 51 and covers the light shielding layer 52, and the gate insulating layer 54 is disposed on the buffer layer 53 and covers the active layer 10. The gate 20 and the gate auxiliary structure 40 are disposed on the gate insulating layer 54, the dielectric layer 55 is disposed on the gate insulating layer 54 and covers the gate 20 and the gate auxiliary structure 40. The source 31 and the drain 32 penetrate the dielectric layer 55 and part of the gate insulating layer 54.

With reference to FIG. 2, FIG. 2 illustrates a schematic structural diagram of a top view of the display panel in FIG. 1 according to one or more embodiments of the present disclosure.

As shown in FIG. 1 and FIG. 2, the gate auxiliary structure 40 is disposed on a side wall of the gate 20 along the first direction (X), and an orthographic projection of the first transition layer 131 on the gate auxiliary structure 40 is within the gate auxiliary structure 40, that is, the gate auxiliary structure 40 and the first transition layer 131 are on a same side of the gate 20.

The display panel 100 includes a gate layer 20a on the gate insulating layer 54. A thickness of the gate layer 20a is equal to a thickness of the gate auxiliary structure 40, and the gate layer 20a surrounds a side wall of the gate auxiliary structure 40, that is, the gate auxiliary structure 40 is embedded in the gate layer 20a. A portion of the gate layer 20a between the gate auxiliary structure 40 and the second ohmic contact layer 122 is the gate 20, that is, a portion of the gate layer 20a directly above the channel layer 11 is the gate 20.

The display panel 100 may also include a gate wiring 20b connected to the gate 20, and the gate wiring 20b is disposed on the gate insulating layer 54. A width of the gate wiring 20b along the first direction (X) is greater than a width D1 of the gate 20 along the first direction (X), which ensures conductivity of the gate wiring 20b.

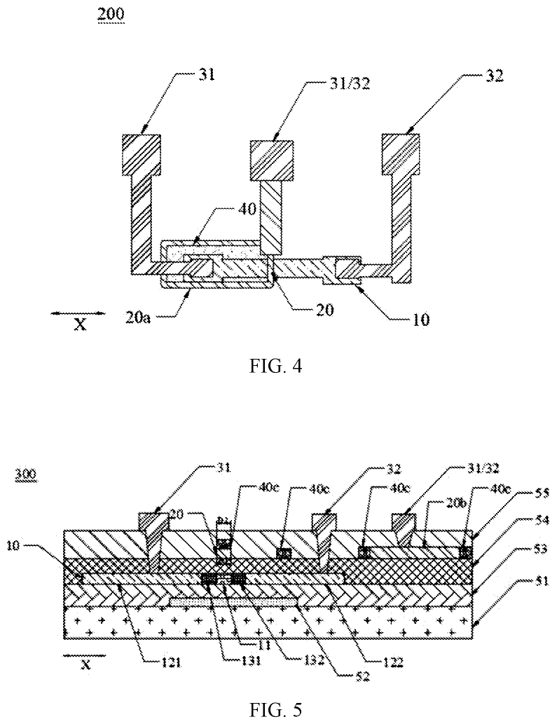

With reference to FIG. 3 and FIG. 4, FIG. 3 illustrates a schematic structural diagram of a cross-sectional view of a display panel according to one or more embodiments of the present disclosure, while FIG. 4 illustrates a schematic structural diagram of a top view of the display panel in FIG. 3 according to one or more embodiments of the present disclosure. In order to facilitate understanding and brief explaining of the present disclosure, one or more embodiments use the same numeral references for the same structure as the foregoing embodiment, and the same structure will no longer be described in detail. Only differences from the foregoing embodiment will be explained.

In one or more embodiments, in a display panel 200, orthographic projections of the first transition layer 131 and the first ohmic contact layer 121 on the gate auxiliary structure 40 are both within the gate auxiliary structure 40. Namely, the gate auxiliary structure 40 extends from the first transition layer 131 to the first ohmic contact layer 121, covering a portion of the active layer 10 that is disposed on a left side of the channel layer 11. Therefore, a portion of the gate 20 opposite to the gate layer 20a does not cover the active layer 10, so that a region where the active layer 10 overlaps with the gate layer 20a only includes the gate 20, which can reduce a coupling capacitance between the gate layer 20a and the active layer 10.

FIG. 3 is different from FIG. 1 in that the source 31 penetrates the gate auxiliary structure 40.

With reference to FIG. 5, FIG. 5 illustrates a schematic structural diagram of a cross-sectional view of a display panel according to one or more embodiments of the present disclosure. In order to facilitate understanding and brief explaining of the present disclosure, one or more embodiments use the same numeral references for the same structure as the foregoing embodiment, and the same structure will no longer be described in detail. Only differences from the foregoing embodiment will be explained.

In one or more embodiments, in a display panel 300, the gate auxiliary structure 40c is on the gate 20, and a width D2 of the gate auxiliary structure 40c along the first direction (X) is equal to a width D1 of the gate 20 along the first direction (X). The active layer 10 includes a first ohmic contact layer 121, a second ohmic contact layer 122, a first transition layer 131, a second transition layer 132, and a channel layer 11. The second transition layer 132 is disposed between the second ohmic contact layer 122 and the channel layer 11.

In one or more embodiments, the gate auxiliary structure 40c overlaps with the gate 20.

In one or more embodiments, the gate auxiliary structure 40c are also disposed above the second ohmic contact layer 122 and disposed on two side walls of the gate wiring 20b along the first direction (X).

The display panel according to one or more embodiments of the present disclosure includes the active layer 10 and the gate 20. The active layer 10 is disposed along the first direction (X) and includes the channel layer 11. The gate 20 is opposite to and above the channel layer 11, and the width D1 of the gate 20 along the first direction (X) is equal to the length L of the channel layer 11 along the first direction (X). The width D1 of the gate 20 along the first direction (X) is less than 1 μm, so that the length L of the channel layer 11 along the first direction (X) is also less than 1 μm. A gate 20 with an extremely small width is realized, thereby obtaining the channel layer 11 with an extremely small width. A migration rate of the display panel is improved, the area of the display panel is reduced, and the aperture ratio of the display panel is improved. Also, development of a product with high resolution and high refresh rate is facilitated, even functions of some chips are realized.

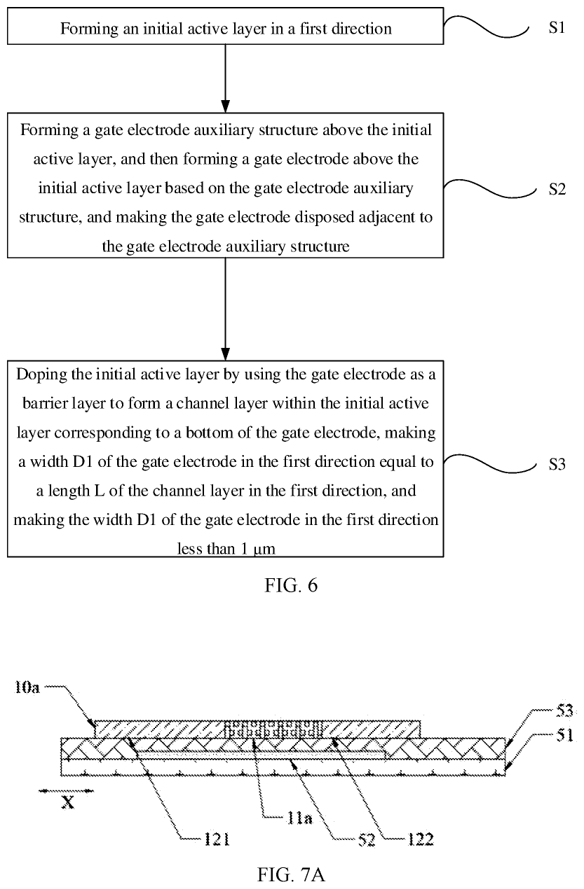

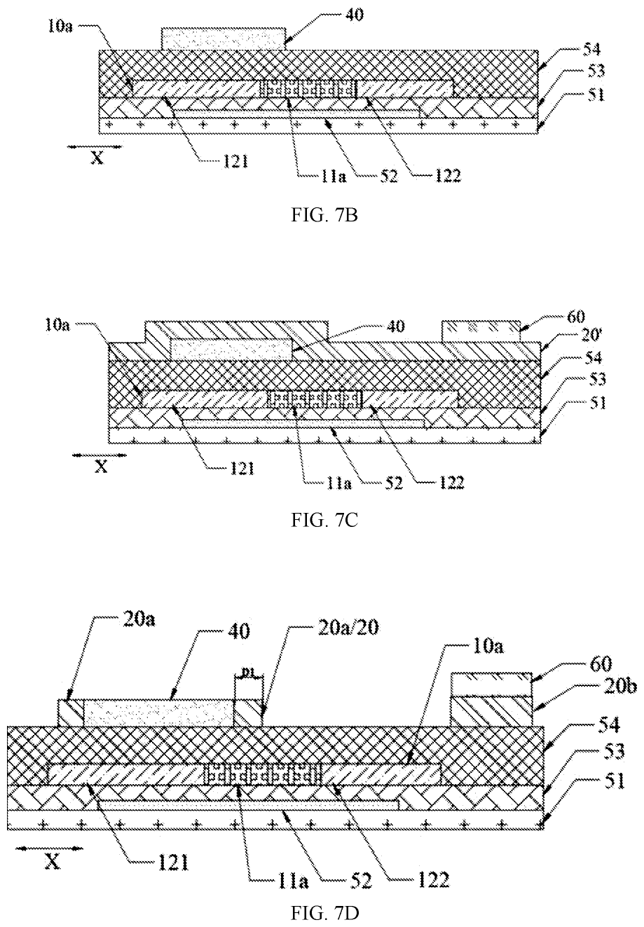

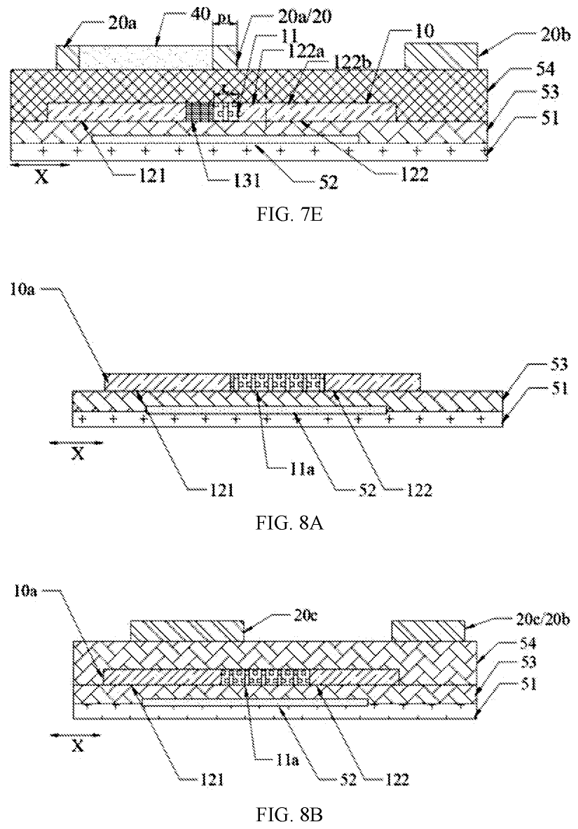

With reference to FIG. 6, FIG. 6 illustrates a schematic flowchart of a manufacturing method of the display panel according to one or more embodiments of the present disclosure. While also with reference to FIGS. 7a to 7e, FIGS. 7a to 7e illustrate schematic structural diagrams of a display panel during a manufacturing method according to one or more embodiments of the present disclosure. In one or more embodiments, the display panel 100 is taken as the example to explain the manufacturing method of the display panel 100. Therefore, the manufacturing method of the display panel 100 includes steps S1˜S3 with reference to FIG. 1 and FIG. 2.

At S1, an initial active layer 10a is formed along a first direction (X).

In one or more embodiments, as shown in FIG. 7A, a light shielding layer 52 may be first formed on a substrate 51, a buffer layer 53 covering the light shielding layer 52 is formed on the substrate 51, and an active material layer along the first direction (X) is formed on the buffer layer 53. Next, heavy ion doping is applied to two ends of the active material layer to form the initial active layer 10a. The initial active layer 10a includes a first ohmic contact layer 121, a second ohmic contact layer 122, and an initial channel layer 11a between the first ohmic contact layer 121 and the second ohmic contact layer 122.

At S2, a gate auxiliary structure 40 is formed above the initial active layer 10a, and a gate 20 is formed above the initial active layer 10a based on the gate auxiliary structure 40. The gate 20 is disposed adjacent to the gate auxiliary structure 40.

The S2 may include the following steps: 1) as shown in FIG. 7B, forming a gate insulating layer 54 on the initial active layer 10a; 2) as shown in FIG. 7B, forming the gate auxiliary structure 40 on the gate insulating layer 54, the gate auxiliary structure 40 covering a portion of the initial channel layer 11a along the first direction (X), such as a portion of the initial channel layer 11a covering the first ohmic contact layer 121 and a portion of the initial channel layer 11a connected to the first ohmic contact layer 121; 3) as shown in FIG. 7C, forming a gate material layer 20′ that covers the gate auxiliary structure 40 on the gate insulating layer 54, such as molybdenum (Mo) or molybdenum aluminum alloy (Mo/Al) or molybdenum copper alloy (Mo/Cu) or molybdenum copper and indium zinc oxide alloy (Mo/Cu/IZO) or indium zinc oxide and copper alloy (IZO/Cu/IZO) or molybdenum copper and indium tin oxide alloy (Mo/Cu/ITO) or nickel copper alloy (Ni/Cu/Ni) or molybdenum titanium nickel and copper alloy (MoTiNi/Cu/MoTiNi) or nickel chromium copper alloy (NiCr/Cu/NiCr) or a copper niobium alloy (CuNb), with a thickness of less than 1 μm, e.g., a range of 0.05˜0.5 μm; 4) as shown in FIG. 7D, performing anisotropic etching (i.e., vertical etching) on the gate material layer 20′ to form the gate 20 disposed on the side wall of the gate auxiliary structure 40 along the first direction (X), the gate 20 being above the initial channel layer 11a.

Specially, after the anisotropic etching, a gate layer 20a is formed around the sidewall of the gate auxiliary structure 40. A portion of the gate layer 20a opposite to and above the initial channel layer 11a is determined as the gate 20. Based on film forming characteristics, a width D1 of the gate 20 along the first direction (X) is equal to a thickness of the gate material layer 20′. Based on characteristics of the etching process, a thickness of the gate 20 is equal to a thickness of the gate auxiliary structure 40. Before performing the anisotropic etching process, a photoresist 60 is formed in a region where a gate wiring 20b needs to be formed, thereby to form the gate wiring 20b after etching the gate material layer 20′.

At S3, the initial active layer 10a is doped by using the gate 20 as a barrier layer to form in the initial active layer 10a a channel layer 11 opposite to a bottom of the gate 20. The width D1 of the gate 20 along the first direction (X) is equal to a length L of the channel layer 11 along the first direction (X). The width D1 of the gate 20 along the first direction (X) is less than 1 μm.

As shown in FIG. 7D and FIG. 7E, the initial active layer 10a is doped with slight ions to form a first transition layer 131 and the channel layer 11 in the initial channel layer 11a. The first transition layer 131 is covered by the gate auxiliary structure 40, and the channel layer 11 is opposite to and below the gate 20.

P-type ion slightly doping process may be directly performed on the initial active layer 10a. Due to well blocking performance of the gate 20 and weak blocking performance of the gate auxiliary structure 40, the doped ions can reach the initial channel layer 11a below the gate auxiliary structure 40 by a penetrating manner to form the first transition layer 131. The initial channel layer 11a without doping serves as the channel layer 11, so that the width D1 of the gate 20 along the first direction (X) is equal to the length L of the channel layer 11 along the first direction (X). Due to the width D1 of the gate 20 along the first direction (X) is less than 1 μm, the length L of the channel layer 11 along the first direction (X) is also less than 1 μm.

Since an end of the initial channel layer 11a in contact with the second ohmic contact layer 122 is not covered by the gate auxiliary structure 40, the doped ions on the left side of the gate 20 additionally pass through the gate auxiliary structure 40 compared to the doped ions on the right side. In order to ensure that the slightly doped first transition layer 131 is formed in part of the initial channel layer 11a connected to the first ohmic contact layer 121, a higher doping concentration will be formed in part of the initial channel layer 11a connected to the second ohmic contact layer 122, that is, the part of initial channel layer 11a connected to the second ohmic contact layer 122 will form together with the second ohmic contact layer 122 as a new second ohmic contact layer 122. Therefore, the new second ohmic contact layer 122 may include a first concentration region 122a close to the channel layer 11 and a second concentration region 122b away from the channel layer 11, and a doping concentration of the first concentration region 122a is lower than a doping concentration of the second concentration region 122b. As shown in FIG. 7D, the first ohmic contact layer 121, the first transition layer 131, the channel layer 11, and the second ohmic contact layer 122 together form an active layer 10.

As shown in FIG. 1, the manufacturing method of the display panel 100 may also include forming a source 31 and a drain 32 connected to the first ohmic contact layer 121 and the second ohmic contact layer 122, respectively. A dielectric layer 55 covering the gate 20 and the gate auxiliary structure 40 is formed on the gate insulating layer 54. The dielectric layer 55 and a portion of the gate insulating layer 54 are etched to form a via hole connected to the first ohmic contact layer 121 and the second ohmic contact layer 122. A conductive material is formed within the via holes and on a surface of the dielectric layer 55. The source 31 and the drain 32 are disposed on the dielectric layer 55.

Since there is no other material (e.g., the gate auxiliary structure 40) covering the first ohmic contact layer 121 and the second ohmic contact layer 122, the etching depths in the dielectric layer 55 to form a via hole corresponding to the source 31 and the drain 32 are consistent with each other.

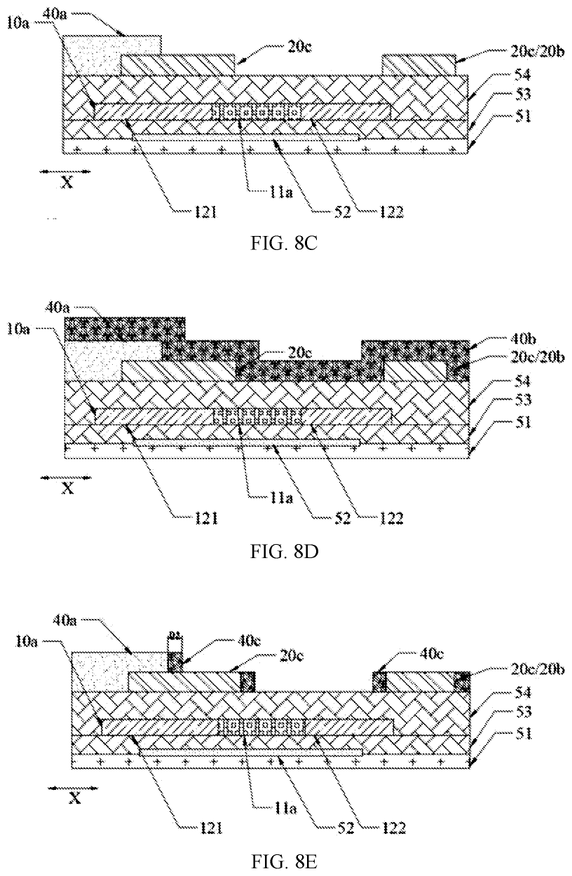

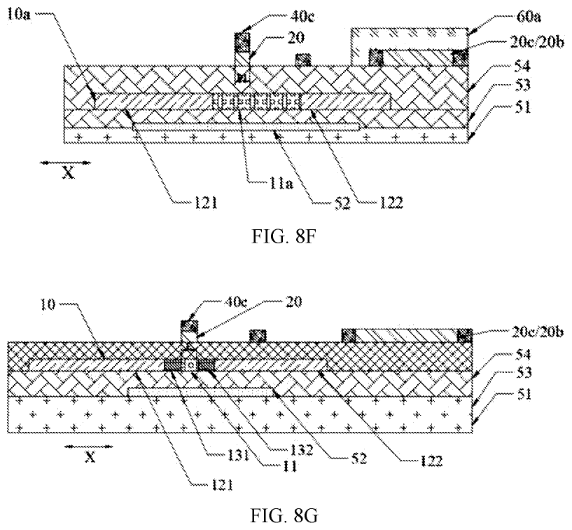

With reference to FIG. 6 and FIGS. 8a to 8g, FIGS. 8a to 8g illustrate schematic structural diagrams of a display panel during a manufacturing method according to one or more embodiments of the present disclosure. In one or more embodiments, the display panel 300 is taken as the example to explain the manufacturing method of the display panel 300 with reference to FIG. 5.

At S1, an initial active layer 10a is formed along a first direction (X).

The specific steps of the step 1 in the foregoing embodiment may be referred to.

At S2, a gate auxiliary structure 40c is formed above the initial active layer 10a, and a gate 20 is formed above the initial active layer 10a based on the gate auxiliary structure 40c. The gate 20 is disposed adjacent to the gate auxiliary structure 40c.

S2 may include steps 1)˜6).

At step 1), as shown in FIG. 8A, a gate insulating layer 54 is formed on the initial active layer 10a.

At step 2), as shown in FIG. 8B, a patterned gate layer 20c is formed on the gate insulating layer 54. The patterned gate layer 20c covers the initial channel layer 11a. The patterned gate layer 20c also includes a gate wiring 20b that does not cover the initial channel layer 11a.

At step 3), as shown in FIG. 8C, a first gate auxiliary layer 40a is formed on the gate insulating layer 54 and the patterned gate layer 20c, and the first gate auxiliary layer 40a covers a portion of the patterned gate layer 20c along the first direction (X). The first gate auxiliary layer 40a may be made of silicon nitride.

At step 4), as shown in FIG. 8D, a second gate auxiliary layer 40b covering the patterned gate layer 20c and the first gate auxiliary layer 40a is formed. The second gate auxiliary layer 40b may be made of silicon oxide.

At step 5), as shown in FIG. 8E, anisotropic etching is performed on the second gate auxiliary layer 40b to form a gate auxiliary structure 40c on a side wall of the first gate auxiliary layer 40a along the first direction (X) and on the patterned gate layer 20c. A width D3 of the gate auxiliary structure 40c along the first direction (X) is equal to a thickness of the second gate auxiliary layer 40b, and the thickness of the second gate auxiliary layer 40b is less than 1 μm, for example, in a range of 0.05˜0.5 μm. Furthermore, the gate auxiliary structure 40c is also formed on a side wall of the patterned gate layer 20c and a side wall of the gate wiring 20b.

At step 6), as shown in FIG. 8F, the patterned gate layer 20c is etched based on the gate auxiliary structure 40c to form a gate 20 opposite to and above the initial channel layer 11a. A width D1 of the gate 20 along the first direction (X) is equal to s width D3 of the gate auxiliary structure 40c along the first direction (X). Due to the width D3 of the gate auxiliary structure 40c along the first direction (X) being less than 1 μm, the width D1 of the gate 20 along the first direction (X) is less than 1 μm. Before etching, a photoresist 60a is covered on the gate wiring 20b to ensure that the gate wiring 20b is not etched.

At S3, the initial active layer 10a is doped by using the gate 20 as a barrier layer to form in the initial active layer 10a a channel layer 11 opposite to and below the gate 20. The width D1 of the gate 20 along the first direction (X) is equal to a length L of the channel layer 11 along the first direction (X). The width D1 of the gate 20 along the first direction (X) is less than 1 μm.

Specifically, as shown in FIG. 8G, the initial active layer 10a is doped with slight ions to form a first transition layer 131, a second transition layer 132, and the channel layer 11 in the initial channel layer 11a. The channel layer 11 is opposite to and below the gate 20, and the first transition layer 131 and the second transition layer 132 are disposed on two ends of the channel layer 11 along the first direction (X).

P-type ion slightly doping process may be directly performed on the initial active layer 10a. Due to well blocking performance of the gate 20, the doped ions cannot reach the initial channel layer 11a below the gate 20 by a penetrating manner, so that the initial channel layer 11a without doping serves as the channel layer 11. Therefore, the width D1 of the gate 20 along the first direction (X) is equal to the length L of the channel layer 11 along the first direction (X). Since the width D1 of the gate 20 along the first direction (X) is less than 1 μm, the length L of the channel layer 11 along the first direction (X) is also less than 1 μm.

The manufacturing method of the display panel according to one or more embodiments of the present disclosure utilizes the gate auxiliary structure to form the gate 20 with an extremely small width, thereby forming the channel layer 11 with an extremely small length based on the gate 20. The width D1 of the gate 20 is determined by the thickness of the film layers, thereby overcoming the accuracy limitations of an exposure machine. The gate wiring 20b in other wiring regions can be designed as the normal width D1, but its conductivity is not affected.

A display device according to one or more embodiments of the present disclosure at least includes the display panel in any one of the foregoing embodiments. The display device has the same beneficial effects as the above display panel, and will not be further described here.

The explanation of the above embodiments is only used to help understand the technical solutions and the core idea of the present disclosure. Those skilled in the related art should understand that they can still modify the technical solutions recorded in the aforementioned embodiments, or equivalently replace some of the technical features. However, these modifications or replacements do not make the essence of the corresponding technical solutions deviate from the scope of the technical solutions of the various embodiments of the present disclosure.

What is claimed is:

1. A display panel, comprising:
an active layer along a first direction, wherein the active layer comprises a channel layer;
a gate above the channel layer, wherein a width of the gate along the first direction is equal to a length of the channel layer along the first direction; and
a gate auxiliary structure adjacent to the gate;
wherein the width of the gate along the first direction is less than 1 micrometer.

2. The display panel according to claim 1, wherein the active layer further comprises:
a first ohmic contact layer and a second ohmic contact layer; wherein the first ohmic contact layer and the second ohmic contact layer are disposed on two ends of the active layer, respectively, and the channel layer is disposed between the first ohmic contact layer and the second ohmic contact layer; and
a first transition layer, wherein the first transition layer is disposed between the first ohmic contact layer and the channel layer.

3. The display panel according to claim 2, wherein the gate auxiliary structure is disposed on a side wall of the gate along the first direction, and an orthographic projection of the first transition layer on the gate auxiliary structure is within the gate auxiliary structure.

4. The display panel according to claim 2, wherein the gate auxiliary structure is disposed on a side wall of the gate along the first direction, and an orthographic projection of the first ohmic contact layer on the gate auxiliary structure is within the gate auxiliary structure.

5. The display panel according to claim 4, wherein the display panel further comprises a source and a drain, the source and the drain are connected to the first ohmic contact layer and the second ohmic contact layer, respectively, and the source penetrates the gate auxiliary structure.

6. The display panel according to claim 2, wherein the active layer further comprises a second transition layer, and the second transition layer is disposed between the second ohmic contact layer and the channel layer.

7. The display panel according to claim 2, wherein the gate auxiliary structure is disposed on the gate and a width of the gate auxiliary structure along the first direction is equal to the width of the gate along the first direction.

8. The display panel according to claim 7, wherein the display panel further comprises a gate wiring connected to the gate,
the gate auxiliary structure is further disposed above a second ohmic contact layer and on two side walls of the gate wiring along the first direction.

9. The display panel according to claim 2, wherein the first ohmic contact layer and the second ohmic contact layer are doped with an N-type semiconductor material, the first transition layer is doped with a P-type semiconductor material, and a doping concentration of each of the first ohmic contact layer and the second ohmic contact layer is greater than a doping concentration of the first transition layer.

10. The display panel according to claim 2, wherein the second ohmic contact layer comprises a first concentration region close to the channel layer and a second concentration region away from the channel layer, and a doping concentration of the first concentration region is lower than a doping concentration of the second concentration region.

11. A display device, wherein the display device comprises a display panel,
the display panel comprises:
an active layer along a first direction, wherein the active layer comprises a channel layer;
a gate above the channel layer, wherein a width of the gate along the first direction is equal to a length of the channel layer along the first direction; and
a gate auxiliary structure adjacent to the gate;
wherein the width of the gate along the first direction is less than 1 micrometer.

12. The display device according to claim 11, wherein the active layer further comprises:
a first ohmic contact layer and a second ohmic contact layer; wherein the first ohmic contact layer and the second ohmic contact layer are disposed on two ends of the active layer, respectively, and the channel layer is disposed between the first ohmic contact layer and the second ohmic contact layer; and
a first transition layer, wherein the first transition layer is disposed between the first ohmic contact layer and the channel layer.

13. The display device according to claim 12, wherein the gate auxiliary structure is disposed on a side wall of the gate along the first direction, and an orthographic projection of the first transition layer on the gate auxiliary structure is within the gate auxiliary structure.

14. The display device according to claim 12, wherein the gate auxiliary structure is disposed on a side wall of the gate along the first direction, and an orthographic projection of the first ohmic contact layer on the gate auxiliary structure is within the gate auxiliary structure.

15. The display device according to claim 14, wherein the display panel further comprises a source and a drain, the source and the drain are connected to the first ohmic contact layer and the second ohmic contact layer, respectively, and the source penetrates the gate auxiliary structure.

16. The display device according to claim 12, wherein the active layer further comprises a second transition layer, and the second transition layer is disposed between the second ohmic contact layer and the channel layer.

17. The display device according to claim 12, wherein the gate auxiliary structure is disposed on the gate and a width of the gate auxiliary structure along the first direction is equal to the width of the gate along the first direction.

18. The display device according to claim 17, wherein the display panel further comprises a gate wiring connected to the gate,
the gate auxiliary structure is further disposed above a second ohmic contact layer and on two side walls of the gate wiring along the first direction.

19. The display device according to claim 12, wherein the first ohmic contact layer and the second ohmic contact layer are doped with an N-type semiconductor material, the first transition layer is doped with a P-type semiconductor material, and a doping concentration of each of the first ohmic contact layer and the second ohmic contact layer is greater than a doping concentration of the first transition layer.

20. The display device according to claim 12, wherein the second ohmic contact layer comprises a first concentration region close to the channel layer and a second concentration region away from the channel layer, and a doping concentration of the first concentration region is lower than a doping concentration of the second concentration region.
